(19) United States
(12) Patent Application Publication
(10) Pub. No.: US 2026/0169098 A1
(43) Pub. Date: Jun. 18, 2026

(54) METHOD FOR BILATERAL BOARD DETECTION USING VOLTAGE THRESHOLDS ON A SINGLE SIGNAL

(71) Applicant: S&C Electric Company, Chicago, IL (US)

(72) Inventor: Douglas Charles Bailey, Waukesha, WI (US)

(73) Assignee: S&C Electric Company, Chicago, IL (US)

(21) Appl. No.: 19/346,927

(22) Filed: Oct. 1, 2025

Related U.S. Application Data
(60) Provisional application No. 63/734,813, filed on Dec. 17, 2024.

(51) Int. Cl. G01R 31/68; G01R 19/165; H02H 9/02

(52) U.S. Cl. CPC G01R 31/68; G01R 19/16504; G01R 19/16547; H02H 9/02

(57) ABSTRACT

A detection system including a first module, a second module and an interface configured to allow the first module and the second module to be detachably coupled to each other. The first module includes a first detection circuit and the second module includes a second detection circuit coupled together on a single detection line. The first detection circuit measures voltage on the single detection line to determine if the second detection circuit is connected thereto and if so, whether the second detection circuit is being powered, and the second detection circuit measures voltage on the single detection line to determine if the first detection circuit is connected thereto and if so, whether the first detection circuit is being powered.

### CROSS-REFERENCE TO RELATED APPLICATION

This application claims the benefit of priority from the U.S. Provisional Application No. 63/734,813, filed on Dec. 17, 2024, the disclosure of which is hereby expressly incorporated herein by reference for all purposes.

### BACKGROUND

### Field

This disclosure relates generally to a detection system that allows a pair of detection circuits to detect each other and, more particularly, to a detection system that can detect whether the detection circuits are connected and powered by measuring voltage on a single detection line.

### Discussion of the Related Art

An electrical power distribution network, often referred to as an electrical grid, typically includes power generation plants each having power generators, such as gas turbines, nuclear reactors, coal-fired generators, hydro-electric dams, etc. The power plants provide power at medium voltages that are then stepped up by transformers to a high voltage AC signal to be connected to high voltage transmission lines that deliver electrical power to substations typically located within a community, where the voltage is stepped down to a medium voltage for distribution. The substations provide the medium voltage power to three-phase feeders including three single-phase feeder lines that carry the same current but are 120° apart in phase. Three-phase and/or single phase lateral lines are tapped off of the feeder that provide the medium voltage to various distribution transformers, where the voltage is stepped down to a low voltage and is provided to loads, such as homes, businesses, etc.

Fault interrupters, for example, reclosers that employ vacuum interrupters, are provided on utility poles and in underground circuits along a power line allow or prevent power flow downstream of the fault interrupter. These fault interrupters typically detect the current and/or voltage on the line to monitor current flow and have controls that indicate problems with the network circuit, such as detecting a high current fault event. If such a high fault current is detected the fault interrupter is opened in response thereto, and then after a short delay closed to determine whether the fault is a transient fault. If high fault current flows when the fault interrupter is closed after opening, it is immediately re-opened. If the fault current is detected a second time, or multiple times, during subsequent opening and closing operations indicating a persistent fault, then the fault interrupter remains open, where the time between detection tests may increase after each test.

Modern “smart” reclosers, such as single-phase reclosers mounted on utility poles, allow a portable communications module to be selectively connected thereto in order to download data, transfer configuration files, power the recloser to close the vacuum interrupter, etc. It is desirable to detect when the connection is made between the recloser and the communications module by both the recloser and the communications module, detect if the recloser and the communications module are being powered by the other recloser or communications module and minimize the complexity of the connection interface between the recloser and the communications module, such as by reducing the connection pin count, where the detections are made by a single line.

### SUMMARY

The following discussion discloses and describes a detection system including a first module, a second module and an interface configured to allow the first module and the second module to be detachably coupled to each other. The first module includes a first detection circuit having a first resistor divider with a first resistor and a second resistor electrically coupled in series. The first detection circuit further includes a first protection diode electrically coupled in parallel with the first resistor, where the first resistor and the cathode of the first protection diode are electrically coupled to a first power input opposite to the second resistor and the second resistor is electrically coupled to ground opposite to the first resistor. The second module includes a second detection circuit having a second resistor divider with a third resistor and a fourth resistor electrically coupled in series. The second detection circuit further includes a second protection diode electrically coupled in parallel with the third resistor, where the third resistor and the cathode of the second protection diode are electrically coupled to a second power input opposite to the fourth resistor and the fourth resistor is electrically coupled to ground opposite to the third resistor. The interface also is configured to allow the first detection circuit and the second detection circuit to be electrically coupled by a single detection line. The detection line is electrically coupled to the anode of the first protection diode, the first resistor divider between the first resistor and the second resistor, the anode of the second protection diode, and the second resistor divider between the third resistor and the fourth resistor. The first detection circuit measures voltage on the detection line to determine if the second detection circuit is connected thereto and if so, whether the second detection circuit is being powered and the second detection circuit measures voltage on the detection line to determine if the first detection circuit is connected thereto and if so, whether the first detection circuit is being powered.

Additional features of the disclosure will become apparent from the following description and appended claims, taken in conjunction with the accompanying drawings.

### BRIEF DESCRIPTION OF THE DRAWINGS

FIG. 1 is an illustration of a portion of a pole unit assembly including a pole unit having a pole unit detection circuit and a communications module having a communications module detection circuit for detecting a connection between the pole unit and the communications module;

FIG. 2 is a schematic diagram of a more detailed pole unit detection circuit;

FIG. 3 is a schematic diagram of a more detailed communications module detection circuit; and

FIG. 4 is a schematic diagram of an interface circuit provided in an interface between the detection circuits shown in FIGS. 2 and 3.

### DETAILED DESCRIPTION OF THE EMBODIMENTS

The following discussion of the embodiments of the disclosure directed to a detection system including a first detection circuit and a second detection circuit that are selectively connectable to each other through an interface, where the first and second detection circuits each can detect whether the detection circuits are connected and powered by measuring voltage on a single detection line is merely exemplary in nature, and is in no way intended to limit the invention or its applications or uses.

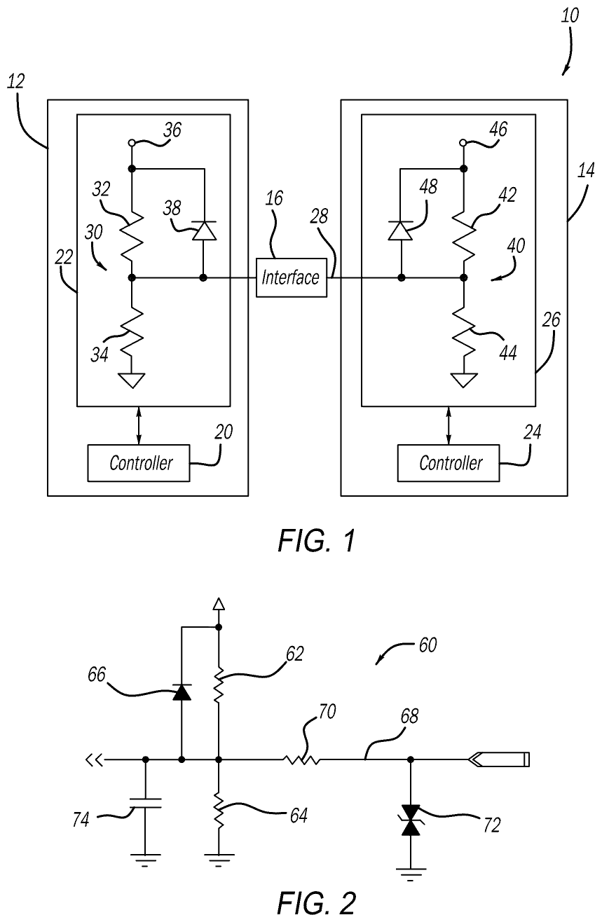

FIG. 1 is an illustration of a portion of a pole unit assembly 10 including a pole unit 12, for example, a single-phase recloser mounted to a utility pole, and a communications module 14 coupled together through a connections interface 16. Although not specifically shown, the interface 16 includes and represents a connector that is part of the pole unit 12 and a connector that is part of the communications module 14 that each include suitable electrical pins and/or sockets so that the communications module 14 can be selectively coupled to and detached from the pole unit 12. The pole unit 12 includes a controller 20 and a pole unit detection circuit 22 and the communications module 14 includes a controller 24 and a communications module detection circuit 26, where the detection circuits 22 and 26 are electrically connected together by a single detection line 28 through the interface 16. The controller 20 controls the operation of the pole unit 12 and measures and processes the various voltages discussed herein and the controller 24 controls the operation of the communications module 14 and measures and processes the various voltages discussed herein. It is noted that although the detection circuit 22 is shown as part of the pole unit 12 and the detection circuit 26 is shown as part of the communications module 14 this is by way of a non-limiting example. The detection circuits 22 and 26 could be part of any suitable system that included separate modules where it is desirable to know if the modules are connected and powered using a single detection line consistent with the discussion herein.

The detection circuit 22 includes a resistor divider 30 having a resistor 32 and a resistor 34, where power is provided to the resistor 32 at node 36, the resistor 34 is connected to ground and the detection line 28 is connected between the resistors 32 and 34. The detection circuit 22 also includes a protection diode 38 whose cathode is connected to the node 36 and whose anode is connected to the line 28 in parallel with the resistor 32 that protects the detection circuit 22 if the circuit 22 is not being powered. Likewise, the detection circuit 26 includes a resistor divider 40 having a resistor 42 and a resistor 44, where power is provided to the resistor 42 at node 46, the resistor 44 is connected to ground and the detection line 28 is connected between the resistors 42 and 44. The detection circuit 26 also includes a protection diode 48 whose cathode is connected to the node 46 and whose anode is connected to the line 28 in parallel with the resistor 42 that protects the detection circuit 26 if the circuit 26 is not being powered.

As will be discussed, the configuration of the detection circuits 22 and 26 allows the detection circuit 22 to know if the detection circuit 26 is connected to the detection circuit 22 and if so, whether the detection circuit 26 is being powered, and allows the detection circuit 26 to know if the detection circuit 22 is connected to the detection circuit 26 and if so, whether the detection circuit 22 is being powered, all on the single detection line 28. In this design, the resistive value of the resistor 32 is twice as much as the resistive value of the resistor 34, and the resistor 44 has the same resistive value as the resistor 32 and the resistor 42 has the same resistive value as the resistor 34.

Both of the circuits 22 and 26 measure the voltage on the detection line 28. That measured voltage is different for the circuits 22 and 26 when either of the circuits 22 and 26 is not connected to the line 28, the circuits 22 and 26 are connected, but not powered, and the circuits 22 and 26 are connected and are powered. If the circuits 22 and 26 are connected and both are powered, then both of the circuits 22 and 26 read half of the voltage on the line 28. If the circuits 22 and 26 are not connected, then the circuit 22 reads one-third of the voltage on the line 28 and the circuit 26 reads two-thirds of the voltage on the line 28. If the circuits 22 and 26 are connected and the circuit 26 is not powered, then the circuit 22 reads the voltage drop across the diode 48. If the circuits 22 and 26 are connected and the circuit 22 is not powered, then the circuit 26 reads the voltage drop across the diode 38.

Stated another way, the detection circuit 22 will measure 0.33 of the voltage on the detection line 28 if the circuits 22 and 26 are not connected and will read 0.5 of the voltage on the line 28 if the circuits 22 and 26 are connected and the detection circuit 26 is powered. The detection circuit 22 will also read a minimum forward voltage of the protection diode 48 and a maximum voltage of the resistor divider of the resistor 32 and the parallel combination of the resistor 34 and the resistor 44 (depending on loading at the node 46) if the circuits 22 and 26 are connected and the circuit 26 is not powered. The circuit 26 will read 0.67 of the voltage on the detection line 28 if the circuits 22 and 26 are not connected and will read 0.5 of the voltage on the line 28 if the circuits 22 and 26 are connected and the detection circuit 22 is powered. The circuit 26 will also read a minimum forward voltage of the protection diode 38 and a maximum voltage of the resistor divider of the resistor 42 and the parallel combination of the resistor 34 and the resistor 44 (depending on loading at the node 36) if the circuits 22 and 26 are connected and the detection circuit 22 is not powered.

Table 1 lists the equations for the detect voltage on the line 28 for all of the configurations, where VDD1 is the voltage at the node 36, VDD2 is the voltage at the node 46, R1 is the resistor 32, R2 is the resistor 34, R3 is the resistor 42 and R4 is the resistor 44.

TABLE 1

| | | Power | |
|---|---|---|---|
| | | ON | |
| | | status of | |
| | | the | |
| | | other | |
| Device | Attached | circuit | Detected Voltage |
| Circuit 22 | No | N/A | Detect (V) = VDD1(V)*(R2)/(R1 + R2) |
| Circuit 22 | Yes | No | Detect(V) = Range of Vf1 to |
| | | | VDD1(V)*(R2\| \|R4)/(R1 + R2\| \|R4) |
| Circuit 22 | Yes | Yes | Detect(V) = (VDD1(V)*(1/R1) + |
| | | | VDD2(V)*(1/R3))*(1/((1/R1) + (1/ |
| | | | R2) + (1/R3) + (1/R4) |
| Circuit 26 | No | N/A | Detect(V) = VDD2(V)*(R4)/(R3 + R4) |
| Circuit 26 | Yes | No | Detect(V) = Range of Vf2 to |
| | | | VDD2(V)*(R2\|\|R4)/(R1 + R2\|\|R4) |
| Circuit 26 | Yes | Yes | Detect(V) = (VDD1(V)*(1/R1) + |
| | | | VDD2(V)*(1/R3))*(1/((1/R1) + (1/ |
| | | | R2) + (1/R3) + (1/R4)) |

FIG. 2 is a schematic diagram of a detection circuit 60 that is a more detailed representation of the detection circuit 22 for use on a pole unit. The circuit 60 includes a pull up resistor 62 representing the resistor 32, a pull down resistor 64 representing the resistor 34 and a protection diode 66 representing the diode 38, where a detection line 68 is connected between the resistors 62 and 64. In this non-limiting example, the resistor 62 has a value of 1 Meg Ohm and the resistor 64 has a value of 499K Ohm. The circuit 60 also includes a 1K Ohm current limiting resistor 70 in the detection line 68, a protection diode 72 coupled to the detection line 68 and 0.1 μF filtering capacitor 74 coupled to the detection line 68.

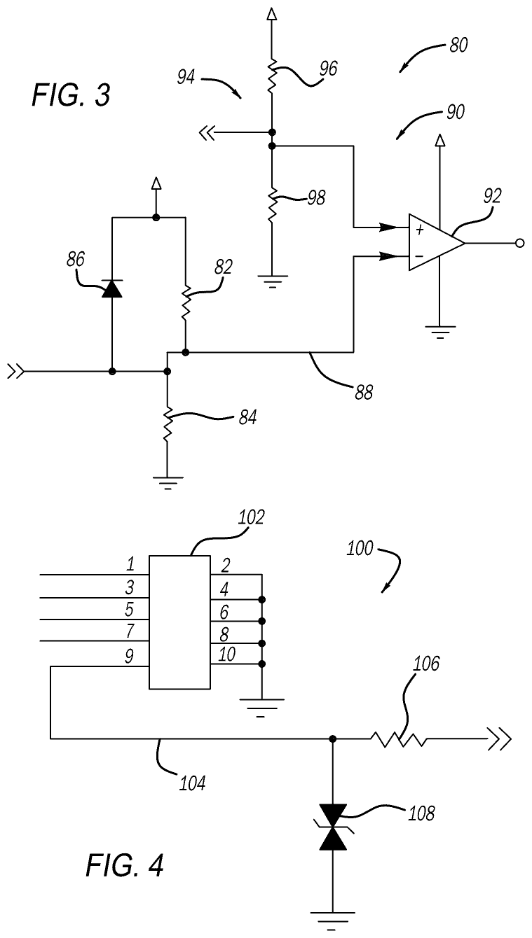

FIG. 3 is a schematic diagram of a detection circuit 80 that is a more detailed representation of the detection circuit 26 for use on a communications module. The circuit 80 includes a pull up resistor 82 representing the resistor 42, a pull down resistor 84 representing the resistor 44 and a protection diode 86 representing the diode 48, where a detection line 88 is connected between the resistors 82 and 84. In this non-limiting example, the resistor 84 has a value of 1 Meg Ohm and the resistor 82 has a value of 499K Ohm. The circuit 80 also includes a wake-up sub-circuit 90 having a comparator 92 that receives the voltage on the detection line 88 at a negative input and a reference voltage from a voltage divider circuit 94 having resistors 96 and 98 at a positive input. If the voltage on the negative input exceeds the reference voltage then the output of the comparator 92 goes high, which causes downstream circuits and/or controllers to wake up.

FIG. 4 is a schematic diagram of an interface circuit 100 provided in an interface between the detection circuits 60 and 80 and includes a connector 102 that is the connector associated with the detection circuit 60. A detection line 104 is coupled to pin 9 of the connector 102, where a current limiting resistor 106 is provided in the line 104 and a protection diode 108 is coupled to the line 104. Pins 1, 3, 5, 7 and 9 would be used for other features of the circuits 60 and 80.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A detection system comprising:
a first module including a first detection circuit, the first detection circuit including a first resistor divider having a first resistor and a second resistor electrically coupled in series, the first detection circuit further including a first protection diode electrically coupled in parallel with the first resistor, wherein the first resistor and a cathode of the first protection diode are electrically coupled to a first power input opposite to the second resistor and the second resistor is electrically coupled to ground opposite to the first resistor;
a second module including a second detection circuit, the second detection circuit including a second resistor divider having a third resistor and a fourth resistor electrically coupled in series, the second detection circuit further including a second protection diode electrically coupled in parallel with the third resistor, wherein the third resistor and a cathode of the second protection diode are electrically coupled to a second power input opposite to the fourth resistor and the fourth resistor is electrically coupled to ground opposite to the third resistor; and
an interface configured to allow the first module and the second module to be detachably coupled to each other and allow the first detection circuit and the second detection circuit to be electrically coupled by a single detection line, the detection line being electrically coupled to the anode of the first protection diode, the first resistor divider between the first resistor and the second resistor, the anode of the second protection diode, and the second resistor divider between the third resistor and the fourth resistor, wherein the first detection circuit measures voltage on the detection line to determine if the second detection circuit is connected thereto and if so, whether the second detection circuit is being powered and the second detection circuit measures voltage on the detection line to determine if the first detection circuit is connected thereto and if so, whether the first detection circuit is being powered.

2. The detection system according to claim 1 wherein the first resistor has a resistive value that is twice as much as the resistive value of the second resistor, the third resistor has the same resistive value as the second resistor and the fourth resistor has the same resistive value as the first resistor.

3. The detection system according to claim 2 wherein if the first and second detection circuits are connected and both are powered, then the first and second detection circuits both measure half of the voltage on the detection line, if the first and second detection circuits are not connected, then the first detection circuit measures one-third of the voltage on the detection line and the second detection circuit measures two-thirds of the voltage on the detection line, if the first and second detection circuits are connected and the second detection circuit is not powered, then the first detection circuit measures a voltage drop across the second protection diode, and if the first and second detection circuits are connected and the first detection circuit is not powered, then the second detection circuit measures a voltage drop across the first protection diode.

4. The detection system according to claim 1 wherein the first module is a pole unit and the second module is a communications device.

5. The detection system according to claim 4 wherein the pole unit is a recloser.

6. A detection system comprising:
a first detection circuit including a first resistor divider having a first resistor and a second resistor electrically coupled in series, wherein the first resistor is electrically coupled to a first power input opposite to the second resistor and the second resistor is electrically coupled to ground opposite to the first resistor;
a second detection circuit including a second resistor divider having a third resistor and a fourth resistor electrically coupled in series, wherein the third resistor is electrically coupled to a second power input opposite to the fourth resistor and the fourth resistor is electrically coupled to ground opposite to the third resistor; and
a detection line electrically coupled to the first resistor divider between the first resistor and the second resistor and the second resistor divider between the third resistor and the fourth resistor, wherein the first detection circuit measures voltage on the detection line to determine if the second detection circuit is connected thereto and if so, whether the second detection circuit is being powered and the second detection circuit measures voltage on the detection line to determine if the first detection circuit is connected thereto and if so, whether the first detection circuit is being powered.

7. The detection system according to claim 6 wherein the first detection circuit further includes a first protection diode electrically coupled in parallel with the first resistor and the second detection circuit further includes a second protection diode electrically coupled in parallel with the third resistor, and wherein a cathode of the first protection diode is electrically coupled to the first power input, an anode of the first protection diode is electrically coupled to the detection line, a cathode of the second protection diode is electrically coupled to the second power input and an anode of the second protection diode is electrically coupled to the detection line.

8. The detection system according to claim 6 further comprising an interface configured to allow the first detection circuit and the second detection circuit to be detachably coupled to each other, the detection line extending through the interface.

9. The detection system according to claim 6 wherein the first resistor has a resistive value that is twice as much as the resistive value of the second resistor, the third resistor has the same resistive value as the second resistor and the fourth resistor has the same resistive value as the first resistor.

10. The detection system according to claim 9 wherein if the first and second detection circuits are connected and both are powered, then both of the first and second detection circuits measure half of the voltage on the detection line, if the first and second detection circuits are not connected, then the first detection circuit measures one-third of the voltage on the detection line and the second detection circuit measures two-thirds of the voltage on the detection line.

11. The detection system according to claim 6 wherein the first detection circuit is part of a pole unit and the second detection circuit is part of a communications device.

12. The detection system according to claim 11 wherein the pole unit is a recloser.

13. A detection system comprising:
a pole unit including a first detection circuit, the first detection circuit including a first resistor divider having a first resistor and a second resistor electrically coupled in series, the first detection circuit further including a first protection diode electrically coupled in parallel with the first resistor, wherein the first resistor and a cathode of the first protection diode are electrically coupled to a first power input opposite to the second resistor and the second resistor is electrically coupled to ground opposite to the first resistor, and wherein the first resistor has a resistive value that is twice as much as the resistive value of the second resistor;
a communications module including a second detection circuit, the second detection circuit including a second resistor divider having a third resistor and a fourth resistor electrically coupled in series, the second detection circuit further including a second protection diode electrically coupled in parallel with the third resistor, wherein the third resistor and a cathode of the second protection diode are electrically coupled to a second power input opposite to the fourth resistor and the fourth resistor is electrically coupled to ground opposite to the third resistor, and wherein the third resistor has the same resistive value as the second resistor and the fourth resistor has the same resistive value as the first resistor; and
an interface configured to allow the pole unit and the communications module to be detachably coupled to each other and allow the first detection circuit and the second detection circuit to be electrically coupled by a single detection line, the detection line being electrically coupled to an anode of the first protection diode, the first resistor divider between the first resistor and the second resistor, an anode of the second protection diode, and the second resistor divider between the third resistor and the fourth resistor, wherein if the first and second detection circuits are connected and both are powered, then the first and second detection circuits both measure half of the voltage on the detection line, if the first and second detection circuits are not connected, then the first detection circuit measures one-third of the voltage on the detection line and the second detection circuit measures two-thirds of the voltage on the detection line, if the first and second detection circuits are connected and the second detection circuit is not powered, then the first detection circuit measures a voltage drop across the second protection diode, and if the first and second detection circuits are connected and the first detection circuit is not powered, then the second detection circuit measures a voltage drop across the first protection diode.

14. The detection system according to claim 13 wherein the pole unit is a recloser.

15. The detection system according to claim 13 wherein the first and fourth resistors have a resistance value of 1 Meg Ohm and the second and third resistors have a resistance value of 499K Ohm.
